(19) United States
(12) Patent Application Publication
(10) Pub. No.: US 2005/0070043 A1
(43) Pub. Date: Mar. 31, 2005

(54) Semiconductor device and method for manufacturing the same

(76) Inventors: Koji Yamakawa, Tokyo (JP); Katsuaki Natori, Yokohama-shi (JP); Soichi Yamazaki, Yokohama-shi (JP); Osamu Arisumi, Yokohama-shi (JP); Hiroshi Itokawa, Yokohama-shi (JP); Hiroyuki Kanaya, Yokohama-shi (JP); Kazuhiro Tomioka, Yokohama-shi (JP); Keisuke Nakazawa, Tokyo (JP); Yasuyuki Taniguchi, Tokyo (JP); Uli Egger, Tokyo (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/673,247

(22) Filed: Sep. 30, 2003

(51) Int. Cl. B23Q 3/157; H01L 21/00

(52) U.S. Cl. 438/54

(57) ABSTRACT

The present invention provides a method for manufacturing a semiconductor device equipped with a capacitor in which a dielectric film is used, wherein a complex oxide is used as a mask material when the dielectric film is etched.

### BACKGROUND OF THE INVENTION

1. Field of the Invention

The present invention relates to a semiconductor device equipped with a capacitor using a dielectric film and a method for manufacturing the semiconductor device.

2. Description of the Related Art

In recent years, a ferroelectric random access memory (FeRAM), which is a nonvolatile memory utilizing a ferroelectric thin film, has been under development. An FeRAM is a DRAM whose capacitor portion is replaced by a ferroelectric substance. A semiconductor device equipped with a ferroelectric capacitor is disclosed in Jpn. Pat. Appln. KOKAI Publication No. 2002-289809.

In the FeRAM, a ferroelectric thin film of such a substance as PZT (Pb(ZrₓTi₁₋ₓ)O₃), BIT (Bi₄Ti₃O₁₂) or SBT (SrBi₂Ta₂O₉) is used for a capacitor portion. Any of these substances has a crystal structure based on a perovskite structure having an oxygen octahedron as a basic structure.

The ferroelectric thin film of PZT or the like is crystallized on a lower electrode, and hence it is greatly affected by a structure and electric properties of the lower electrode. Leakage properties, C—V properties, polarization properties, change with time of electric properties, retention properties, fatigue properties, etc. of the ferroelectric thin film depend on a material and a structure of an electrode, especially, the structure of the lower electrode.

It has been investigated to use an Ir-based or a Ru-based thin film material for this lower electrode. The electrode of the Ir-based or the Ru-based material, which is different from a Pt electrode conventionally used, has a problem that crystallinity (orientation or fine structure of crystals) of the ferroelectric film of PZT or the like formed on the electrode deteriorates, and a problem that Ru or Ir reacts with Pb in a boundary face or these elements are diffused into grain boundaries to increase a leakage current. Therefore, it is necessary to more accurately control a manufacturing process of the above electrode. Further, in order to improve the fatigue properties, there has been carried out, e.g., the introduction of an oxide layer into a boundary face between the ferroelectric substance and the electrode.

A thermal budget, a process in a reducing atmosphere and a process in vacuum for the manufacture of the capacitor are closely concerned with reliabilities of a capacitor itself. The PZT capacitor is seriously damaged by all of insulation film CVD processing, capacitor processing RIE hard mask CVD film formation, hard mask RIE processing, contact RIE processing, photo-resist ashing, forming-gas annealing for reservation of transistor properties, etc.

Furthermore, to manufacture a highly integrated capacitor of a high capacity, processing is necessary for every material of noble metal substances (Pt, Ir, Ru, IrO₂, RuO₂, etc.) which is used for the electrode, laminated structures of them, complex oxide electrodes (SrRuO₃, (Ba, Sr)RuO₃, LaNiO₃, (La, Sr)CoO₃, YBCO, etc.), laminated structures of them, combinations with noble metal electrodes, and capacitor thin-film materials such as PZT, PLZT and BST. None of these materials has a compound having a high vapor pressure, so that it is difficult to chemically dry-etch them. Therefore, RIE is utilized to chemically and mechanically perform the etching. To increase the vapor pressure of the compound, RIE has been tried, for example, at a high temperature (250-350° C.).

Taking fine processing of these capacitors into account, it is desirable to enhance a density of each capacitor in a state where a side wall of the capacitor is as perpendicular as possible. However, in this case, fences comprising these compounds are readily formed. In addition, since it is difficult to perform the RIE processing of each substance, for example, a large difference of an etching rate cannot be acquired between the substances (e.g., between the capacitor and the electrode material), thereby making it difficult to perform selective etching.

### BRIEF SUMMARY OF THE INVENTION

An aspect of the present invention provides a semiconductor device equipped with a capacitor using a dielectric film, wherein a mask material used in etching the dielectric film is prepared as an electrode of the capacitor.

Another aspect of the present invention is directed to a method for manufacturing a semiconductor device equipped with a capacitor using a dielectric film, wherein a complex oxide is used as a mask material when the dielectric film is etched.

### BRIEF DESCRIPTION OF THE SEVERAL VIEWS OF THE DRAWING

FIG. 1A shows a structure of a ferroelectric capacitor in an embodiment of the present invention;

FIG. 1B shows a structure of a ferroelectric capacitor in an embodiment of the present invention;

FIG. 2A shows a process flow of a capacitor in an embodiment of the present invention;

FIG. 2B shows a process flow of a capacitor in an embodiment of the present invention;

FIG. 2C shows a process flow of a capacitor in an embodiment of the present invention;

FIG. 2D shows a process flow of a capacitor in an embodiment of the present invention;

FIG. 3A shows a process flow of a capacitor in a conventional example;

FIG. 3B shows a process flow of a capacitor in a conventional example;

FIG. 3C shows a process flow of a capacitor in a conventional example; and

FIG. 3D shows a process flow of a capacitor in a conventional example.

### DETAILED DESCRIPTION OF THE INVENTION

The following will describe embodiments of the present invention with reference to drawings.

In a first embodiment, reference will be made to a method for manufacturing a semiconductor memory equipped with a capacitor using an oxide ferroelectric substance as a dielectric thin film. In this method, the capacitor is processed using a complex oxide such as SRO(SrRuO₃) as a hard mask. A material of the hard mask has a relatively low etching rate in reactive ion etching (RIE) processing as compared to a ferroelectric substance, a dielectric material and a noble metal electrode material such as Pt or Ir, but in the present embodiment, this characteristic is utilized.

A conductive oxide which is also usable as an electrode material of a dielectric capacitor can also be used as a RIE mask material during capacitor processing and be simultaneously also used as the electrode material as it is. In a case where this conductive oxide is used as the electrode material, it is unnecessary to remove a hard mask as described later. The conductive oxide has advantages of improvement in polarization properties, decrease in a leakage current, improvement in crystallinity of a ferroelectric film, improvement in fatigue properties, improvement in retention properties, etc. of the ferroelectric capacitor. In the dielectric thin film capacitor in which BST ((Ba, Sr)TiO₃) etc are used, increase in dielectric constant, decrease in a leakage current, improvement in temperature properties, etc. can be expected.

The main points of a method for manufacturing a semiconductor memory according to the present embodiment are summarized as follows:
1. A complex oxide is used as a mask material during RIE processing of a dielectric thin film capacitor in which an oxide ferroelectric substance is used.
2. As this complex oxide, a conductive oxide such as SRO (SrRuO₃) is used.
3. In a case where the conductive oxide is used as the RIE mask material, the mask material can also be utilized as it is as the electrode after the RIE processing.
4. It is also possible to use Pt, Ir, Ru, IrO₂, RuO₂, or a laminated structure or a mixture of them as a material for the electrode of a dielectric thin film capacitor in which the oxide ferroelectric substance is used.
5. In a specific example, the SRO electrode mask material is applied to a PZT capacitor.

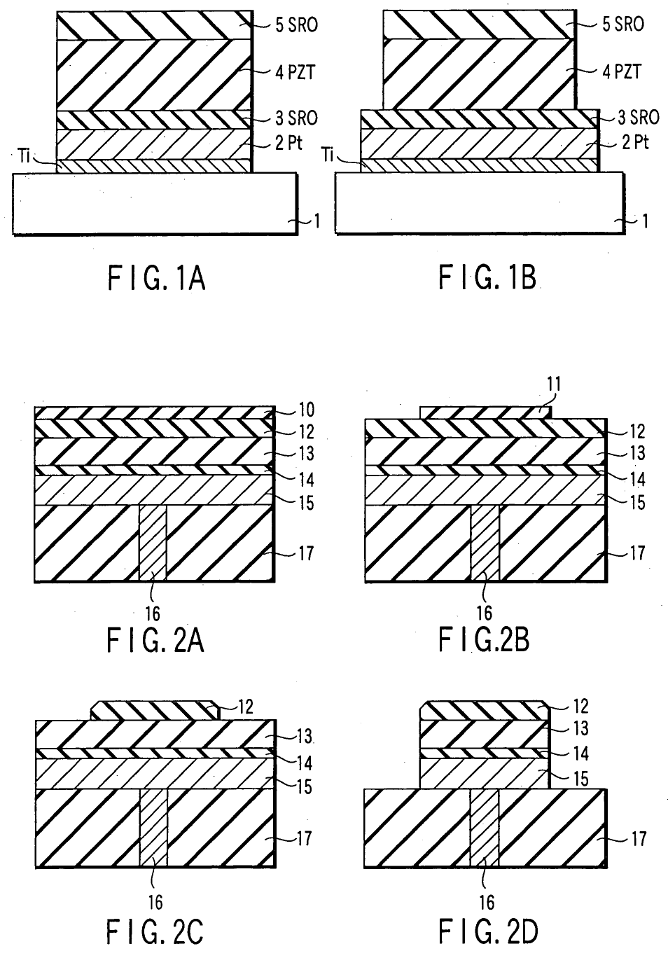

FIG. 1A shows a structure of a ferroelectric capacitor in a first embodiment of the present invention, and FIG. 1B shows a structure of the ferroelectric capacitor obtained by selectively etching the structure of FIG. 1A through a mask. The following will describe steps of a method for manufacturing a ferroelectric memory using a PZT thin film with reference to FIGS. 1A and 1B.

First, a transistor is made on an Si substrate 1 by an ordinary process to form a CMOS structure. An insulation film of PSG, BPSG or the like is formed in a region of the transistor by a CVD method, and its surface is flattened by use of CMP. On the thus flattened surface, an Si oxide film and an SiN film are formed by the CVD method to provide an underlying substrate.

Here, since interconnect of a capacitor and an active area (source/drain) of the transistor is carried out by use of a plug made of W or polycrystalline Si, the plug is beforehand formed. The formation of the plug is accomplished by using both the CVD method and CMP.

First, in formation of a ferroelectric film or a subsequent annealing process in oxygen for securing capacitor properties, a barrier metal layer is formed in order to prevent a surface of the plug from being oxidized. For the barrier layer, TiAlN (Ti/Al=0.9/0.1 (molar ratio) is used. The thickness of the barrier layer is 50 nm. The barrier layer need not be formed all over under a lower electrode of the capacitor, and the barrier layer may be formed only on the plug in a condition where the plug is recessed, or may be formed all over under the lower electrode during the formation of the lower electrode. In accordance with the selected barrier formation manner, the process will slightly change as a whole.

This barrier layer is formed on a connection surface with the plug by use of a DC magnetron sputtering method. On the thus formed barrier layer, an Ir film of the lower electrode is formed by the sputtering method. The thickness of the Ir film is 100 nm. On the Ir film, an IrOₓ film is formed to have a thickness of 50 nm by sputtering under introduction of oxygen. The sputtering operation is performed introducing a sputter power of 1 kW into a target having a diameter of 300 mm at a ratio of Ar/O₂=30/70 at room temperature by the use of a DC magnetron sputter.

In an X-ray diffraction pattern obtained immediately after the formation of these films, a nearly amorphous structure is detected. An observed morphology shows a flat structure on which no characteristic grains are seen. Here, prior to the formation of the ferroelectric film PZT, a heat treatment process such as rapid thermal annealing (RTA) at 550° C. may be performed to improve crystallinity of IrO₂. In this case, a texture grown like a column is observed. An intensity ratio between Ir and IrO₂ is obtained by the X-ray diffraction, and as a result, a large intensity peak of IrO₂ is 10 times or more as much as a small intensity peak of Ir. Alternatively, an IrO₂ layer may be formed by high temperature sputtering at 200 to 400° C. In this case, during the film formation, an IrO₂ crystal film is formed. This texture is the same as in a case where RTA crystallization is performed after the PZT film is formed on the electrode. The Ir layer serves to secure barrier properties to the plug for the oxygen annealing step.

On the other hand, the IrO₂ layer present at a boundary face serves to suppress diffusion into and reaction with the PZT film, thereby decreasing a leakage current.

After the IrO₂ film having a thickness of about 50 nm is formed, a thin film 2 of Pt is formed as a template. The Pt thin film is formed at a temperature of about 200 to 400° C. by a DC magnetron sputtering method, as in the case of the formation of the Ir film. The thickness of the Pt film is about 10 nm. When the Ir film alone is used as an oxygen barrier film, the Pt film as this template is not inserted. This is because if the Pt film is inserted, Si is diffused from the Si plug, silicide reaction with Pt occurs, and the Pt template deteriorates in shape.

On the Ir and Pt layers, an SRO (SrRuO₃) film 3, which contains SRO as a main component, is formed as the lower electrode. The SRO film is formed by DC magnetron sputtering using a conductive ceramic target. Typical sputtering conditions include an atmosphere of Ar, a pressure of 0.5 Pa, a substrate not being heated, and a power of 1 kW. An amorphous SRO film is formed to have a thickness of about 10 to 50 nm. After having been formed by sputtering, the SRO film is heated in an oxygen atmosphere at 600 to 650° C. by RTA, to be crystallized.

Next, a PZT film 4 is formed by sputtering. An RF magnetron sputtering method is employed. In this case, a PZT ceramic target whose Pb content is increased by about 10% is used. The target has a composition of Pb_{1.10}La_{0.05}Zr_{0.4}Ti_{0.6}O₃. As its density increases, the PZT ceramic target has a larger sputtering rate and better environment-resistance against water etc., so that a ceramic sintered compact having a logical density of 98% or higher is used.

Since the sputtering is accompanied by a rise in temperature of the substrate owing to plasma and bombardment by flying grains, Pb is evaporated or re-sputtered from the Si substrate, so that the Pb content in the film is liable to be lost. An excessive Pb content is added to the target in order to compensates for the loss and promote crystallization of the PZT film. Elements such as Zr, Ti, and La are taken into the film at almost the same quantity ratio as a composition of the target, so that a desired composition in quantity of these elements might be employed.

If electric properties are unstable due to the composition of the PZT film etc., conditions for forming an amorphous PZT film are changed. For example, a sputtering method that involves introduction of oxygen is utilized in order to improve a structure and electric properties of a PZT film to be crystallized.

On an underlying Ru film, an amorphous PZT film is formed using only an Ar gas and performing RF magnetron sputtering for about five minutes at a gas pressure of 0.5 to 2.0 Pa and a power of 1.0 to 1.5 kW. It is formed to have a film thickness of 100 to 150 nm. A seed layer may be made of, in place of the PZT film, a Ti film, Zr film, Nb film, or Ta film having a small thickness of 2 to 5 nm.

Further, in order to make constant a condition and a temperature of a target surface and in-chamber environments before the PZT film is formed, pre-sputtering is performed for about 10 minutes to one hour under the same sputtering conditions. This pre-sputtering has a great influence on the Pb content and the post-crystallization structure and electric properties.

On a structure in which the amorphous PZT film is formed on the Ir-based electrode formed via the barrier layer on the plug, the PZT film is crystallized utilizing RTA. A crystal structure of the film thus obtained has been investigated by X-ray diffraction, to find extremely intense reflection being obtained from a face (111) in a perovskite phase.

Next, an SRO (SrRuO₃) film 5, which contains SRO as a main component, is formed as an upper electrode of the capacitor on the PZT crystal film by DC magnetron sputtering. The upper electrode has low reactivity with a ferroelectric substance and so encounters less leakage even when it has undergone a thermal treatment process such as RTA. At this point in time, the SRO film is supposed to have a thickness of 10 to 100 nm.

Furthermore, a photo-resist is formed on the SRO film to pattern it. In this case, without heating the substrate, a gas mainly composed of Ar is used to etch the SRO film physically. The SRO film is difficult to etch chemically at room temperature even by using ordinary chlorine-based and fluorine-based gases. Therefore, fine patterns are formed by physical etching. If proper etch selectivity with respect to the photo-resist cannot be obtained when RIE is performed on the SRO film, a hard mask of an Si oxide is formed on the SRO film before RIE is performed.

After the photo-resist is removed by ashing, this SRO film is used as a mask material to perform reactive ion etching (RIE) on the PZT film and the lower electrode (3). In this process, the PZT film is etched using a CF₄-based gas without heating the substrate.

Further, RIE is performed on the Pt and Ir films of the lower electrode while introducing a Cl-based gas. The SRO upper electrode (5) is etched by such a gas slowly and so acts as a hard mask when RIE is performed on the PZT film and the lower electrode. Further, RIE can be performed also at a high temperature in this process.

The PZT film and the Pt—/Ir-based lower electrode are processed using a Cl-based gas. In this case, etch selectivity with respect to the SRO film is high, so that good SRO mask properties can be obtained. The capacitor can be configured of this PZT capacitor by using this SRO hard mask as it is as the upper electrode.

Ferroelectricity of the PZT film has been investigated against hysteresis properties of a charge quantity Q vs. an application voltage V and, as a result, found to be about 30 μC/cm² at a polarization quantity of 2 Pr (residual polarization×2) in a condition where 2.5V is applied, thus proving the PZT film having almost the same polarization quantity and coercive electric field everywhere on a surface of an eight-inch Si wafer. A small coercive voltage value of about 0.6V has been obtained.

The present inventor has evaluated fatigue properties of this PZT film. The present inventor has evaluated the fatigue properties on an array that corresponds to an area of 50 μm by 50 μm and found that the polarization quantity stays unchanged until the power is cycled 1E12 times and a leakage current has a small value in an order of 10⁻⁸ A/cm² in a condition where 3V is applied.

A contact from the upper electrode of the capacitor is formed using ordinary LSI manufacturing steps. That is, wiring lines are led out from the capacitor by repeating RIE and a wiring line film formation step on the insulation film.

As for a second embodiment, a method is described for forming a capacitor for a ferroelectric random access memory (FeRAM). This method performs an ordinary step for forming a CMOS transistor and then a step for forming the capacitor for the FeRAM.

First, a plug is formed for forming a contact with a source/drain portion of a transistor. A contact hole is formed by RIE in an insulation film composed mainly of SiO₂.

Next, Ti/TiN films are formed. On the TiN film, a W film is formed by blanket W—CVD. After the contact hole is filled, portions of the W film other than the contact and barrier layer portions of the Ti/TiN films are removed by CMP.

Next, a close-contact layer of Ti is formed by sputtering to have a film thickness of 10 nm. On a lower electrode, a laminated Ir/IrO₂ film is formed by sputtering. The Ir/IrO₂ layers have an effect to suppress poor contact from occurring owing to oxidization of an upper face of a plug, in a step (RTO at 600 to 700° C. in the presence of oxygen) for crystallizing a ferroelectric film and an electrode film and an annealing step (annealing at 450 to 650° C. in the presence of oxygen) for recovering the capacitor from process damages. Ir/IrO₂ well serves as a barrier against oxygen. To improve crystallinity of the IrO₂ film, preferably the film is formed by sputtering at a temperature of 200 to 400° C. The Ir/IrO₂ film needs to have a thickness of about 150 nm. On it, a Pt layer for making it easy to control crystallization of the ferroelectric film is formed by sputtering.

Next, a thin film SRO layer is formed in order to improve polarization/fatigue properties, imprint properties, and retention properties of a ferroelectric PZT film. It is formed to have a thickness of 20 nm or less. When it has been formed by sputtering at room temperature, it is crystallized by RTO at about 600° C. On the SRO layer, the ferroelectric PZT film is formed using an RF sputter. In this case, the film is formed by sputtering at room temperature using a ceramic target having a composition of Pb_{1.10}Zr_{0.4}Ti_{0.6}O₃. Further, to crystallize the PZT film, an RTO process at 600 to 700° C. is utilized.

On the crystallized PZT film, an SRO film that provides an upper electrode and a hard mask is formed. This SRO film is given by forming an amorphous film by sputtering and crystallizing it at 600 to 700° C. in an RTO process as in the case of the lower electrode SRO film. It is desired to have a thickness of about 50 to 100 nm.

After a capacitor film structure is formed as described above, processing steps are entered. First, on the upper electrode SRO film, an Si oxide film serving as a hard mask is formed utilizing TEOS, CVD, etc. This hard mask is utilized only to form the upper electrode SRO film, so that its thickness itself needs only to be about 200 nm. The capacitor film is processed utilizing an RIE process at a high temperature of 300 to 400° C. It is done so in order to process the capacitor having an electrode structure of Ir, IrO₂, Pt, etc., at a large taper angle.

Typically, when RIE is performed on an FeRAM capacitor using noble metal, it is difficult to process Pt and Ir (a gas seed having a high vapor pressure is difficult to form. A fence of the noble metal is formed on a side of the capacitor), so that the capacitor is fabricated in a shape having a reduced taper angle. This shape makes it difficult to form a fine capacitor, so that in order to realize a high integration-density FeRAM, it is necessary to process the capacitor at a larger taper angle. One method for this purpose is to utilize high-temperature RIE.

After the Si oxide film is processed with an F-based gas to form the hard mask, the upper electrode SRO film is processed. In this case, RIE is performed using an Ar gas and a mixture of Cl-based and F-based gases. It is no problem even if part of the hard mask of the Si oxide is left un-removed after SRO process. This is because, in such a case, the residual hard mask of the Si oxide film is etched off when PZT or the lower electrode is processed next time.

Next, the PZT film is processed. In this case, the upper electrode SRO film serves as a hard mask essentially. The PZT film is processed using an F-based gas such as CF₄ and a Cl-based gas such as Cl. In this processing, the upper electrode SRO film has a small etching rate and so functions as the hard mask.

Next, a gas system is changed, to process the lower electrode of Pt, Ir, and IrO₂. In this case also, the upper electrode SRO film functions as a hard mask. This is because the SRO film has high etch selectivity with respect to Pt, Ir, and IrO₂. After the lower electrode is processed, processing of the capacitor is completed in a condition where the upper electrode SRO film is left as un-removed.

The capacitor as formed by the present process has its upper electrode made of SRO only and so can be kept free of process damages due to a catalytic effect of the Pt electrode. A Pt-based or Ir-based noble metal electrode activates hydrogen by its catalytic action in a reducing process such as CVD of an Si oxide film, RIE (especially, high-temperature RIE) of a hydrogen system, ashing, or sintering, thus giving reduction damages to a conductive material such as SRO and the PZT film. However, SRO etc., which configures a non-Pt-based electrode, has strong reduction-resistance and may not be subject to the process damages. Further, since the SRO electrode after the capacitor is processed has its upper edge etched off and so is tapered, it is possible to prevent a fence from being formed thereon.

Furthermore, as for an ordinary Si oxide film-based hard mask, in fine processing of the capacitor, the hard mask gradually shrinks as RIE goes on, so that an area of the capacitor (especially, an area of the upper electrode) is decreased highly possibly. The capacitor area has a direct influence on a quantity of charge led to a bit line and so is an item that must be controlled accurately. From this point of view also, an SRO hard mask having high etch selectivity is effective.

In comparison to a conventional capacitor, problems of using a hard mask such as an Si oxide or TiN or TiAlN are enumerated as follows.
Since etch selectivity is small with respect to a capacitor electrode material or a ferroelectric material such as PZT, it is necessary to use a thick hard mask. A problem of deterioration of the capacitor occurs owing to process damages (due to TEOS, CVD, etc.) or a film stress at the time of formation of the thick hard mask.
It is necessary to accurately control a thickness of a hard mask. If the hard mask is thin, it is etched starting from its peripheral portion in processing of the capacitor, so that a shape and an area of the upper electrode change. This in turn changes a quantity of charge induced on the capacitor, thereby making it impossible to obtain a stable signal voltage on the bit line.
A thick hard mask causes a fence to be formed readily on a sidewall of the hard mask at the time of capacitor processing. This fence, which is mainly made of the upper electrode material, gives rise to structural and electrical defects in the subsequent processes.
Since a hard mask is left un-removed after the capacitor is processed, the capacitor has an increased height, so that a contact hole leading to a transistor portion in the subsequent wiring step must be deep and so is difficult to form. Although a method is available to remove the hard mask, an additional step is necessary.

Next, besides the SRO film described above, hard mask materials that can be used according to a similar concept are enumerated below. Basically, such materials are required as to have a small etching rate for a gas system used when RIE is performed on a noble metal electrode of the FeRAM capacitor or ferroelectric materials such as PZT and SBT. Materials expected to have the same effects as those of SRO are enumerated below.
SRTO(Sr(Ru, Ti)O₃:TiO-50 mol %)
   This is a solid solution of SRO and STO (SrTiO₃) and its resistivity increases as STO is added more. It can be used as an electrode material as far as STO is added not more than about 50%. It has high reduction-resistance as compared to SRO.
CaRuO₃ etc., (Sr, Z)RuO₃ etc.
   This is a conductive oxide similar to SRO. It has a crystal structure in which SRO is replaced by Sr or Ca. Further, also a material obtained by replacing some of the Sr elements by Ba or Ca elements in this oxide can be used as an electrode material.
SrIrO₃
   This is a conductive oxide that exhibits low resistivity in a stoichiometric composition. It is produced using an SRO-component element and Ir used to form the lower electrode.
BaPbO₃, BaPb1-xBixO₃
   This is a conductive oxide having a positive temperature coefficient of resistivity. If Bi is added to it, this oxide exhibits even superconductivity.
LSCO((La, Sr)CoO₃)
   This is a conductive oxide having the same perovskite structure as SRO or PZT. It is used in many cases as an electrode of the PZT capacitor.
LNO(LaNiO₃)

This is a conductive oxide having the same perovskite structure as SRO or PZT. It is used in many cases as an electrode of the PZT capacitor.
Others including oxide super-conductive materials
   Oxide high-temperature super-conductive materials such as YBCO and Bi are used. They include YbaCuO etc.
Semiconductor version of perovskite oxide A semiconductor-version oxide obtained by preparing STO in a reducing atmosphere or by performing reducing thermal treatment on it is used. Alternatively, a semiconductor-version oxide obtained by adding a donor element such as La or Nb or an acceptor element such as Fe or Al is used. Parent materials that can be used include STO as well as CaTiO₃, BaTiO₃, and a solid solution of them.

These materials can be used also as a hard mask in the present invention. They all exhibit conductivity and so can be used as the upper electrode after they are processed as the hard mask. The film can be formed by sputtering (DC magnetron sputtering, RF magnetron sputtering, helicon sputtering, ion beam sputtering, etc.), laser abrasion, PVD such as EB evaporation, sol-gel processing, CSD such as MOD, CVD such as MOCVD, etc. Further, it is crystallized by in-situ crystallization to form the film at a high temperature or ex-situ crystallization to crystallize the film utilizing RTP etc. after it is formed.

The following will describe a process for processing a capacitor using a conductive oxide as a hard mask, with reference to the drawings.

FIGS. 2A-2D show the process flow of processing the capacitor according to the second embodiment. In this process, as shown in FIG. 2A, on a plug portion (plug for connection of the capacitor lower electrode) 16 to be connected to a transistor portion, a laminated structure of an Ir (Pt) electrode film 15 configuring the capacitor lower electrode and a lower SRO electrode film 14 is fabricated. To secure close-contact-ness of the Ir electrode film 15 to an insulation film (CMOS upper insulation film) 17, a Ti layer is introduced (which is emitted in the figure). On the Ir electrode film 15/lower SRO electrode film 14, a PZT film 13 is formed. On the crystallized PZT film 13, an upper SRO electrode 12 is formed.

Next, as shown in FIG. 2A, on the capacitor film, a hard mask (hard mask film for processing of the upper electrode) 10 made of an Si oxide film is formed in a plasma TEOS process etc. The upper SRO electrode 12 is configured of a thin film having a thickness of about 100 nm in order to improve electric properties of the PZT film. Next, in a lithography process, a photo-resist pattern is formed on the hard mask 10 and, as shown in FIG. 2B, its hard mask Si oxide film is etched by RIE to form a hard mask (hard mask for processing of the upper electrode) 11.

Next, as shown in FIG. 2C, RIE is performed on the upper SRO electrode (which serves as both the upper electrode and the hard mask) 12. At this step also, RIE is performed using a Cl-based gas. The etching is performed at a high temperature of 300° C. or higher so that a shape of the capacitor may have a large taper angle. If the taper angle need not be large, RIE may be performed at room temperature. SRO has a small etching rate in performing of RIE and finds it difficult to have high etch selectivity with respect to the Si oxide film and other films, so that the hard mask 11 disappears mostly when RIE is performed.

Next, as shown in FIG. 2D, using a pattern of this upper SRO electrode 12 as a hard mask, the PZT film 13 and the lower SRO electrode film 14/Ir electrode film 15 are processed. The PZT film 13 is processed using a Cl-based or F-based gas. In this case, the upper SRO electrode 12 acts as a hard mask because a RIE rate of the PZT film 13 is larger than that of SRO. The lower SRO electrode film 14 has a small film thickness of about 10 nm in order to improve electric properties of the PZT film, which thickness is such as to bring about no problem, in particular, in performing of RIE. Further, the Ir electrode film 15 undergoes RIE by use of a Cl-based etching gas.

By thus providing the upper SRO electrode film as the hard mask, it is possible to process the PZT film 13 and the lower SRO electrode film 14. The completed capacitor is in a condition where an edge of the upper SRO electrode 12 is etched off a little.

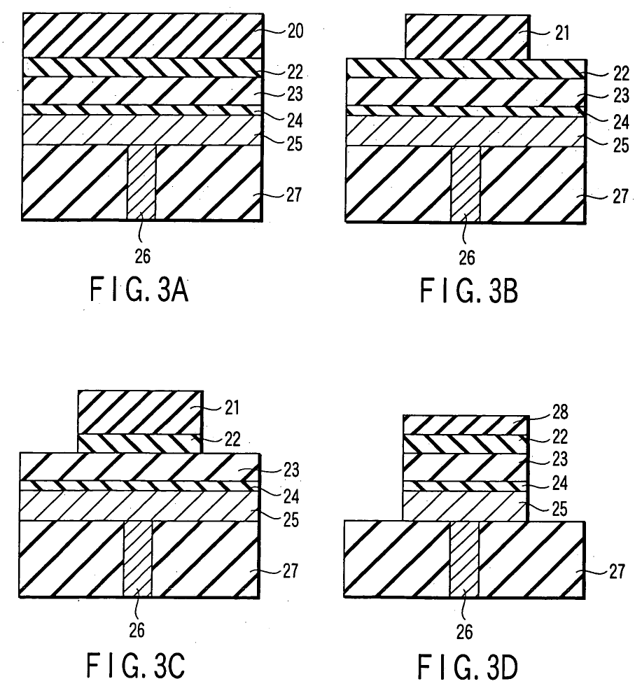

FIGS. 3A-3D show a process flow of processing a conventional capacitor. In this case, the flow is the same as that of the present invention shown in FIGS. 2A-2D except for a hard mask process. In this process, as shown in FIG. 3A, on a plug portion (plug for connection of the capacitor lower electrode) 26 to be connected to a transistor portion, a laminated structure of an Ir (Pt) electrode film 25 configuring a capacitor lower electrode and a lower SRO electrode film 24 is fabricated. To secure close-contact-ness of the Ir electrode film 25 to an insulation film (CMOS upper insulation film) 27, a Ti layer is introduced (which is omitted in the figure). On the Ir electrode film 25/lower SRO electrode film 24, a PZT film 23 is formed. On the crystallized PZT film 23, an upper SRO electrode 22 is formed.

Next, as shown in FIG. 3A, on the capacitor film, a thick hard mask (hard mask film for processing of the upper electrode) 20 made of an Si oxide film is formed in a plasma TEOS process etc. Next, in a lithography process, a photo-resist pattern is formed on the hard mask 20 and, as shown in FIG. 3B, its hard mask Si oxide film is etched by RIE to form a hard mask (hard mask for processing of the upper electrode) 21.

Next, as shown in FIG. 3C, RIE is performed on the upper SRO electrode (which serves as both the upper electrode and the hard mask) 22. At this step also, RIE is performed using a Cl-based gas. The etching is performed at a high temperature of 300° C. or higher so that a shape of the capacitor may have a large taper angle. If the tape angle need not be large, RIE may be performed at room temperature. SRO has a small etching rate in performing of RIE and finds it difficult to have high etch selectivity with respect to the Si oxide film and other films. Therefore, the hard mask 21 needs to be formed thick at the time of RIE and shrinks gradually during the etching.

Next, as shown in FIG. 3D, using this hard mask Si oxide film (hard mask 21), the PZT film 23 and the lower SRO electrode film 24/Ir electrode film 25 are processed. The PZT film 23 is processed using a Cl-based or F-based gas. In this process, the hard mask 21 shrinks more. The lower SRO electrode film 24 has a small film thickness of about 10 nm in order to improve electric properties of the PZT film 23. Further, the Ir electrode film 25 undergoes RIE by use of a Cl-based etching gas.

The completed capacitor is in a condition where a hard mask Si oxide film (residual mask 28) is left un-removed on the upper SRO electrode 22. It is also possible to remove the hard mask by a wet method or a dry etching in the subsequent process. Further, an edge of the upper SRO electrode 22 is not tapered in shape.

Although in the above embodiments the structure configured of the SRO electrode-and-hard mask, the PZT film, and the Ir electrode film/lower SRO electrode film has been described, the same effects can be obtained when any other materials and structures are employed. As a material of the upper electrode-and-hard mask, the material system described above can be used. The ferroelectric film employed may be a PZT film as well as SBT (SrBi₂Ta₂O₉) with or without an additive of Nb, BLT(Bi, La)₄Ti₃O₁₂, PZT to which a variety of elements are added, and a ferroelectric complex oxide such as PLZT. The lower electrode may be made of Ir as well as Pt, Ru, RuO₂, IrO₂, a laminated structure or a mixture of them, etc. Also, the film thickness is not limited to the values given above as far as a process in which the plug is not oxidized is employed.

By the present invention, it is possible to provide a method for manufacturing a semiconductor device that improves properties and processibility of a capacitor using a dielectric film and the semiconductor device. That is, it is possible to provide a method for manufacturing a semiconductor device that can improve electric properties and fatigue properties of the dielectric film and process an electrode more finely without damaging the capacitor in manufacturing steps, and the semiconductor device.

The present invention is not limited to the embodiments described above and can be modified in application without departing from a gist thereof.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method for manufacturing a semiconductor device equipped with a capacitor in which a dielectric film is used, wherein a complex oxide is used as a mask material when the dielectric film is etched.

2. The method according to claim 1, wherein the complex oxide contains SrRuO₃ as a main component.

3. The method according to claim 1, wherein the complex oxide is a conductive oxide, and the mask material is used as an electrode of the capacitor or part of the electrode after the etching.

4. The method according to claim. 1, wherein a laminated structure of a conductive oxide and another conductive film or an insulation film is used as the mask material.

5. The method according to claim 1, wherein the dielectric film contains PZT as a main component.

6. The method according to claim 1, wherein Pt, Ir, Ru, IrO₂, RuO₂, or a laminated structure or a mixture of them is used as a material of an electrode of the capacitor.

7. A semiconductor device equipped with a capacitor in which a dielectric film is used, wherein,a mask material used in etching the dielectric film is prepared as an electrode of the capacitor.

8. The semiconductor device according to claim 7, wherein the dielectric film is a ferroelectric film.

9. The device according to claim 8, wherein the ferroelectric film is PZT.

10. The device according to claim 7, wherein Pt, Ir, Ru, IrO₂, RuO₂, or a laminated structure or a mixture of them is used as a material of the electrode of the capacitor.
